(19) United States
(12) Patent Application Publication
(10) Pub. No.: US 2020/0211980 A1
(43) Pub. Date: Jul. 2, 2020

(54) FAN-OUT PACKAGE WITH WARPAGE REDUCTION AND MANUFACTURING METHOD THEREOF

(71) Applicant: Powertech Technology Inc., Hukou Township (TW)

(72) Inventor: Kun-Yung Huang, Hukou Township (TW)

(73) Assignee: Powertech Technology Inc., Hukou Township (TW)

(21) Appl. No.: 16/233,883

(22) Filed: Dec. 27, 2018

(51) Int. Cl. H01L 23/00; H01L 23/498; H01L 23/31; H01L 21/56; H01L 23/538

(52) U.S. Cl. CPC H01L 23/562; H01L 23/49822; H01L 24/16; H01L 23/3135; H01L 25/0655; H01L 21/568; H01L 23/5383; H01L 2224/16227; H01L 23/3128

(57) ABSTRACT

A fan-out package with warpage reduction has a redistribution layer (RDL), at least one bare chip and a multi-layer encapsulation. A plurality of metal bumps on an active surface of each bare chip are respectively and electrically connected to a plurality of inner pads of the RDL. The multi-layer encapsulation is formed on the RDL to encapsulate the least one bare chip and at least has two different encapsulation layers with different coefficient of thermal expansions (CTE) to encapsulate different portions of sidewalls of each bare chip. One of the encapsulation layers with the smallest CTE is close to RDL. Therefore, in a step of forming the multi-layer encapsulation at high temperature, the suitable CTEs of the encapsulation layers are selected to reduce a warpage between the encapsulation layer and a material layer thereto.

### BACKGROUND OF THE INVENTION

### 1. Field of the Invention

The present invention is related to a fan-out package, and more particularly to a fan-out package with warpage reduction and manufacturing method thereof.

### 2. Description of the Prior Arts

A Fan-out package manufactured by a fan-out wafer level package (FOWLP) process or a fan-out panel level package (FOPLP) process is thinner than a conventional package with a previously-formed substrate. In the manufacturing method, with reference to FIG. 9, an adhesive layer 41 is formed on a glass carrier 40 and a redistribution layer (hereinafter RDL) 61 is further formed on the adhesive layer 41. A plurality of bare chips 62 are mounted on and electrically connected to the RDL 61. A molding compound 63 is further formed to encapsulate the bare chips 62. The glass carrier 40 is departed from the RDL 61 and then a plurality of outer bumps (not shown in FIG. 9) are formed on an exposed surface of the RDL to complete the Fan-out package 60.

Since the glass carrier 40 is employed in the manufacturing method and a coefficient of thermal expansion (hereinafter CTE) of the molding compound 63 does not match the CTE of the glass carrier 40, a warpage of the wafer or panel easily occurs at the process steps with high temperature. In the next process step or the related equipment, the warpage is not easily solved. The yield and production of the fan-out packages are decreased accordingly.

To overcome the shortcomings of the fan-out package, the present invention provides a fan-out package with warpage reduction to mitigate or obviate the aforementioned problems.

### SUMMARY OF THE INVENTION

An objective of the present invention is to provide a fan-out package with warpage reduction.

To achieve the objective as mentioned above, the fan-out package with warpage reduction has:

a redistribution layer (RDL) having a dielectric body, a plurality of interconnections, a plurality of inner pads and a plurality of outer pads, wherein the interconnections are electrically connected the inner pads to the outer pads;

at least one bare chip having an active surface and a rear surface opposite to the active surface, wherein the active surface has a plurality of metal bumps respectively and electrically connected to the inner pads of the RDL; and

a multi-layer encapsulation mounted on the RDL and encapsulating the at least one bare chip, wherein the multi-layer encapsulation comprises:
a first encapsulation layer encapsulating a first portion of sidewalls of each of the least one bare chip, the metal bumps and the inner pads, wherein the first encapsulation layer has a first coefficient of thermal expansion (CTE); and
a second encapsulation layer formed on the first encapsulation layer to encapsulate a second portion of the sidewalls of each of the least one bare chip, wherein the second encapsulation layer has a second CTE and the first CTE is lower than the second CTE.

Based on the foregoing description, in the fan-out package of the present invention, the multi-layer encapsulation is provided. The multi-layer encapsulation has different encapsulation layers with different CTEs and the first encapsulation layer closest to the RDL may be the lowest CTE. Therefore, in a step of forming the multi-layer encapsulation, the suitable CTEs of the first and second encapsulation layers may be selected to decrease a difference between the CTE of RDL and the CTE of the first encapsulation layer. The warpage between the RDL and the multi-layer encapsulation at the process step with high temperature is reduced accordingly.

To achieve the objective as mentioned above, another fan-out package with warpage reduction has:

a first RDL having a first dielectric body, a plurality of first interconnections and a plurality of first inner pads, wherein the first interconnections are electrically connected to the first inner pads;

at least one bare chip having an active surface and a rear surface opposite to the active surface, wherein the active surface has a plurality of metal bumps respectively and electrically connected to the first inner pads of the first RDL;

a multi-layer encapsulation mounted on the first RDL and encapsulating the at least one bare chip, wherein the multi-layer encapsulation comprises:
a first encapsulation layer encapsulating a first portion of sidewalls of each of the least one bare chip, the metal bumps and the first inner pads, wherein the first encapsulation layer has a first CTE; and
a second encapsulation layer formed on the first encapsulation layer to encapsulate a second portion of the sidewalls of each of the least one bare chip, wherein the second encapsulation layer has a second CTE and the first CTE is lower than the second CTE; and

a second RDL formed on a top of the second encapsulation layer and having a second dielectric body, a plurality of second interconnections, a plurality of second inner pads and a plurality of second outer pads, wherein the second interconnections are electrically connected the second inner pads to the second outer pads.

Based on the foregoing description, in the fan-out package of the present invention, the multi-layer encapsulation is provided. In a step of forming the multi-layer encapsulation, the suitable CTEs of the first and second encapsulation layers may be selected to decrease a difference between the CTE of RDL and the CTE of the first encapsulation layer. The warpage between the RDL and the multi-layer encapsulation at the process step with high temperature is reduced accordingly.

Other objectives, advantages and novel features of the invention will become more apparent from the following detailed description when taken in conjunction with the accompanying drawings.

### BRIEF DESCRIPTION OF THE DRAWINGS

FIGS. 1A to 1F are cross-sectional views of a first embodiment of a fan-out package in accordance with the present invention in different manufacturing method;

FIG. 2 is a cross-sectional view of a second embodiment of a fan-out package in accordance with the present invention;

FIGS. 3A to 3G are cross-sectional views of a third embodiment of a fan-out package in accordance with the present invention in different manufacturing method;

FIGS. 4A to 4C are other cross-sectional views of the first embodiment of a fan-out package in accordance with the present invention in different manufacturing method;

FIG. 5 is a cross-sectional view of a fourth embodiment of a fan-out package in accordance with the present invention;

FIGS. 6A to 6F are cross-sectional views of a fifth embodiment of a fan-out package in accordance with the present invention in different manufacturing method;

FIGS. 7A to 7E are cross-sectional views of a sixth embodiment of a fan-out package in accordance with the present invention in different manufacturing method;

FIG. 8A is a cross-sectional view of a seventh embodiment of a fan-out package in accordance with the present invention;

FIG. 8B is a cross-sectional view of an eighth embodiment of a fan-out package in accordance with the present invention; and

FIG. 9 is a cross-sectional view of a conventional fan-out package in accordance with the prior art.

### DETAILED DESCRIPTION OF THE PREFERRED EMBODIMENTS

The present invention provides a new fan-out package to reduce a warpage at a process step with high temperature. With embodiments and drawings thereof, the features of the present invention are described in detail as follow.

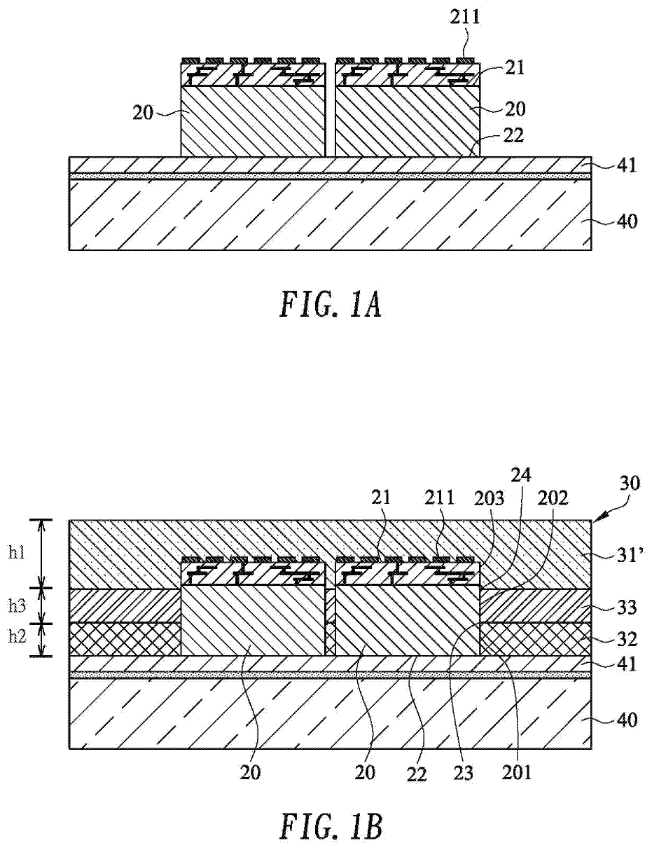

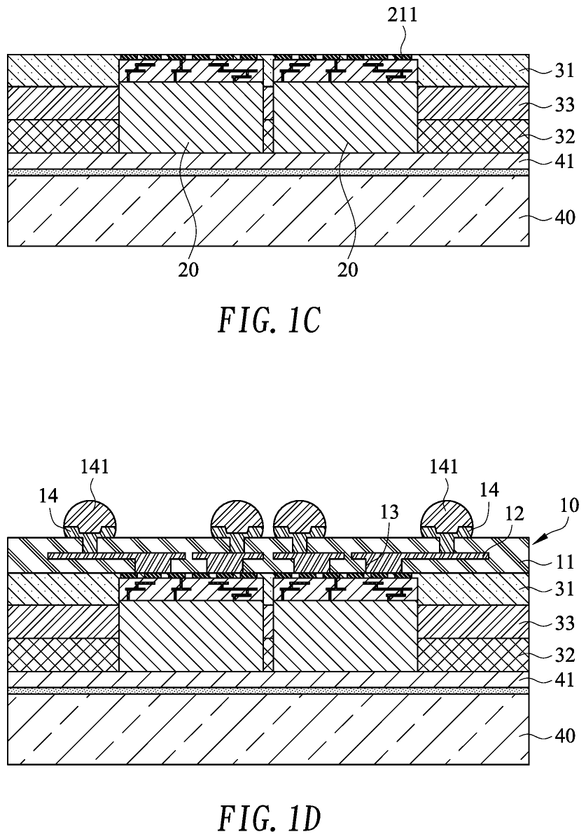

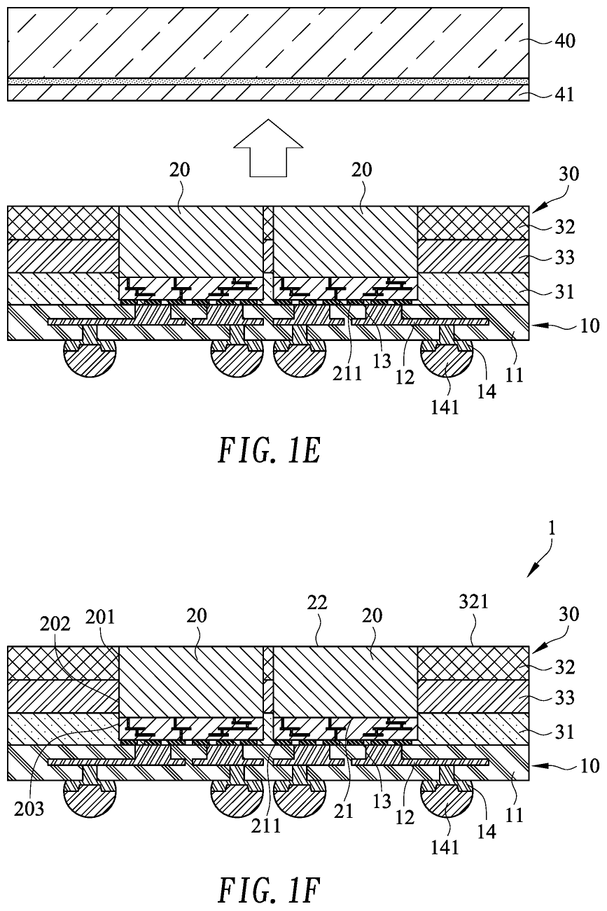

FIG. 1F shows a fan-out package 1 with warpage reduction according to a first embodiment of the present invention. FIGS. 1A to 1E show a manufacturing method of the fan-out package 1 of FIG. 1F. In the first embodiment, the fan-out package is formed using a chip-first packaging process. With reference to 1F, the fan-out package 1 has a first RDL 10, at least one bare chip 20 and a multi-layer encapsulation 30.

The first RDL 10 has a dielectric body 11, a plurality of interconnections 12, a plurality of inner pads 13, and a plurality of outer pads 14. The dielectric body 11 is made of polymer material, such as polyimide. The interconnections 12 may electrically connect the inner pads 13 to the outer pads 14. A plurality of solder balls 141 may be correspondingly formed on the outer pads 14. The outer pads 14 are used to electrically connect to other electronic elements or printed circuit board (PCB).

Each of the bare chips 20 has an active surface 21 and a rear surface 22 opposite to the active surface 21. The active surface 21 has a plurality of metal bumps 211 electrically connected to the corresponding inner pads 13 of the first RDL 10.

The multi-layer encapsulation 30 is formed on the first RDL 10 and encapsulates the bare chips 20. The multi-layer encapsulation 30 may have at least two encapsulation layers to correspondingly encapsulate different portions of sidewalls of each bare chip 20. The two encapsulation layers have different CTEs. The CTE of the encapsulation layer closest to the first RDL 10 may be the lowest. In the first embodiment, the multi-layer encapsulation 30 is formed in sequence of a first encapsulation layer 31, a third encapsulation layer 33, and a second encapsulation layer 32. The first encapsulation 31, the second encapsulation layer 32, and the third encapsulation layer 33 respectively have a first CTE, a second CTE, and a third CTE. The first CTE is lower than the second CTE. The third CTE is lower than the second CTE.

The manufacturing method of the fan-out package 1 shown in FIG. 1F is further described as follow. With reference to FIG. 1A, an adhesive layer 41 is formed on a first surface of a glass carrier 40 to fix the bare chips 20 thereon. The rear surface 22 of each bare chip 20 is adhered to the adhesive layer 41 and the active surface 21 with the metal bumps 211 faces away from the glass carrier 40. With reference to FIG. 1B, the second encapsulation layer 32, the third encapsulation layer 33 and the first encapsulation 31′ are sequentially formed on the first surface of the glass carrier 40. The second encapsulation layer 32 is formed on the first surface of the glass carrier 40 to encapsulate a first portion 201 of the sidewalls of each bare chip 20. The first portion 201 of the sidewalls is a first height position 23 of the sidewalls with reference to the rear surface 22. In FIG. 1B, a label “h2” shows a height of the second encapsulation layer 32. The third encapsulation layer 33 is formed on the second encapsulation layer 32 and encapsulates a second portion 202 of the sidewalls of each bare chip 20. The second portion 202 is between a second height position 24 of the sidewalls and the first height position 23. In FIG. 1B, a label “h3” shows a height of the third encapsulation layer 33. The first encapsulation 31′ is formed on the third encapsulation layer 33 and encapsulates a third portion 203 of the sidewalls of each bare chip 20. The third portion 203 is between the active surface 21 and the second height position 24. In FIG. 1B, a label “h1” shows a height of the first encapsulation layer 31′. In the first embodiment, the first encapsulation 31′ may further encapsulate the metal bumps 211.

With reference to FIGS. 1B and 1C, a thinning process may be performed on the first encapsulation 31′ until the metal bumps 211 are exposed ii form the first encapsulation layer 31. A surface of the first encapsulation layer 31 and a surface of the metal bumps 211 may be coplanar to each other. In addition, the thickness of the first encapsulation layer 31, the second encapsulation layer 32, and the third encapsulation layer 33 may be the same or different from each other after the thinning process. With reference to FIG. 1D, the first RDL 10 may be formed on the first encapsulation layer 31 and the metal bumps 211. The first RDL 10 may be electrically connected to the metal bumps 211. In the first embodiment, the solder balls 141 are correspondingly formed on the outer pads 14 of the RDL 10.

With reference to FIG. 1E, the glass carrier 40 is departed from the fan-out package 1 to complete the final fan-out package 1 as shown in FIG. 1F. The rear surfaces 22 of the bare chips 20 are exposed. With reference to FIG. 1F, a top surface 321 of the second encapsulation layer 32 and the rear surface 22 of each bare chip 20 are coplanar.

Based on the foregoing description of the manufacturing method, after the bare chips 20 are adhered to the glass carrier 40, the multi-layer encapsulation 30 on the glass carrier 40 is formed before forming the first RDL 10. Therefore, the CTE of the second encapsulation layer 32 may be selected to be closest to a CTE of the glass carrier 40. In a next process step with high temperature, the warpage between the glass carrier 40 and the second encapsulation layer 32 is reduced. In addition, since a difference between the CTE of the glass carrier 40 and a CTE of the dielectric body 11 of the first RDL 10 is large, the CTE of the first encapsulation layer 31 may be selected to be closest to the CTE of the dielectric body 11. Therefore, at a next process step with the high temperature, the warpage between the first encapsulation layer 31 and the dielectric body 11 32 is reduced, too.

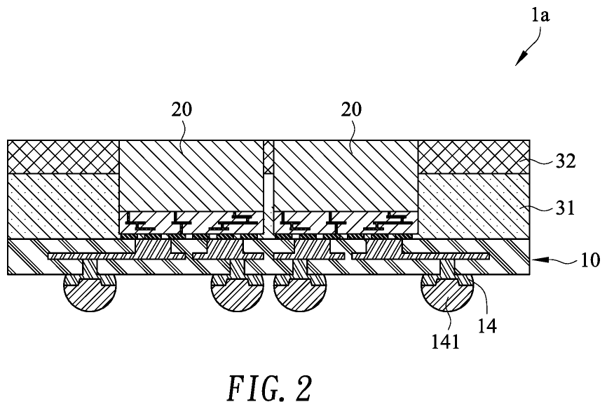

FIG. 2 shows a fan-out package 1a with warpage reduction according to a second embodiment of the present invention. The fan-out package 1a is similar to the fan-out package 1 of FIG. 1F, but a multi-layer encapsulation 30 of the fan-out package 1a only has a first encapsulation layer 31 and a second encapsulation layer 32. A first CTE of the first encapsulation layer 31 is lower than a second CTE of the second encapsulation layer 32. The CTE of the second encapsulation layer 32 may be closer to the CTE of the glass carrier 40 as compared to other encapsulation layers. In addition, the thicknesses of the first and second encapsulation layers may be the same or different.

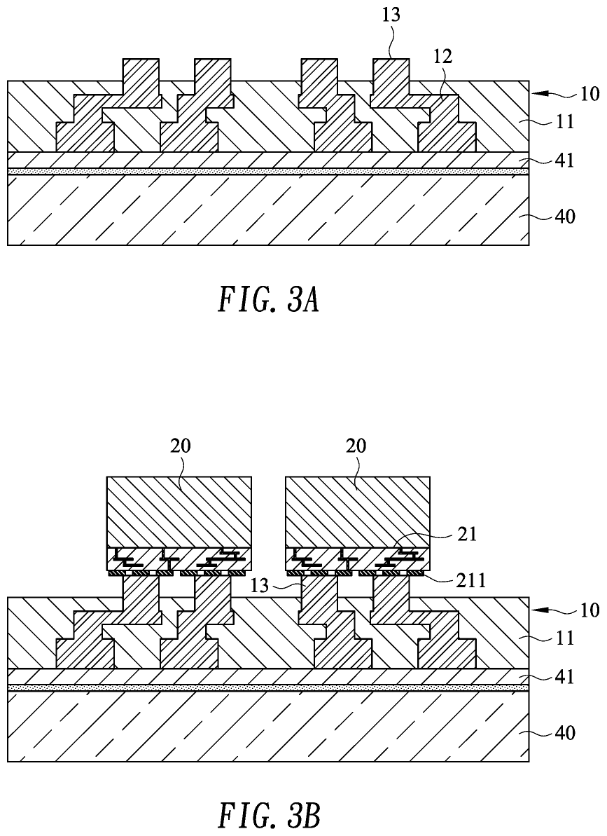

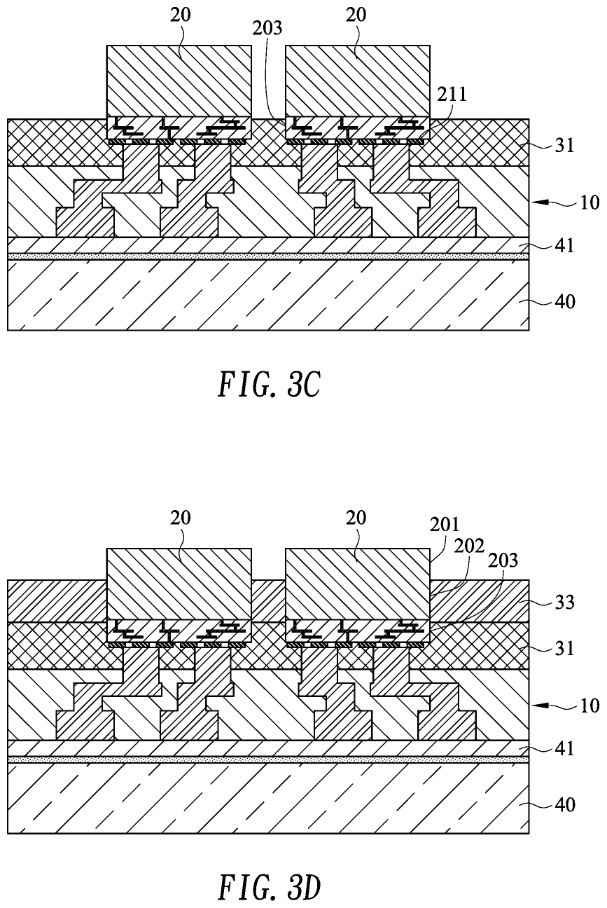

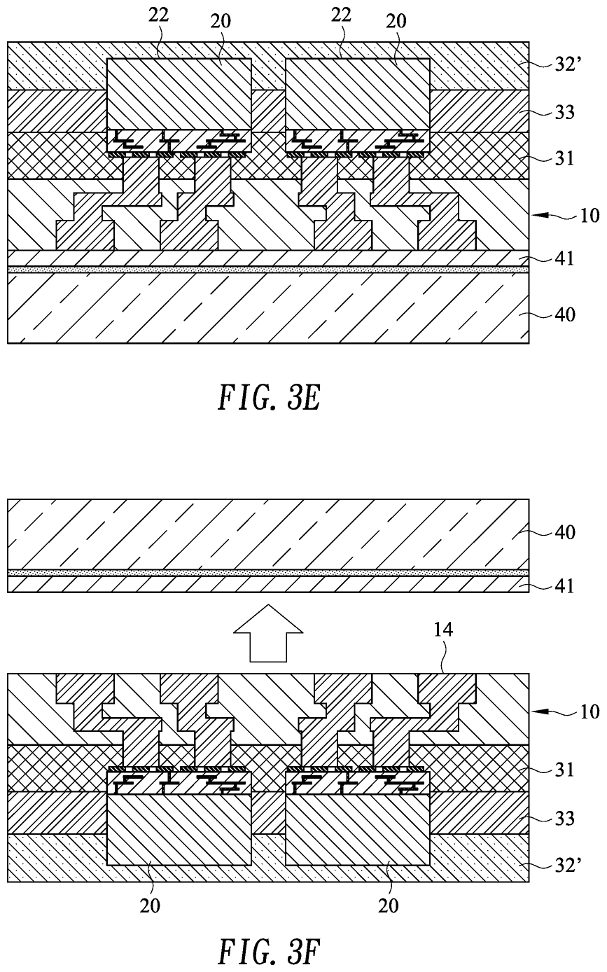

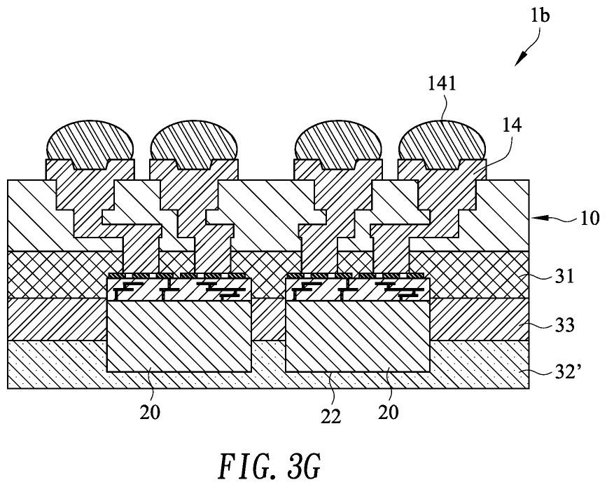

FIG. 3G shows a fan-out package 1b according to a third embodiment of the present invention. FIGS. 3A to 3F show a manufacturing method of the fan-out package 1b FIG. 3G. In the third embodiment, the fan-out manufacturing method is an RDL-first manufacturing method. As shown in FIG. 3G, the fan-out package 1b is similar to the fan-out package 1 as shown in FIG. 1F, but a second encapsulation layer 32′ further covers a rear surface 22 of each bare chip 20.

The manufacturing method of the fan-out package 1b shown in FIG. 3G is further described as follow. With reference to FIG. 3A, an adhesive layer 41 is formed on a first surface of a glass carrier 40 and a first RDL 10 is formed on the adhesive layer 41. A plurality of inner pads 13 of the first RDL 10 are exposed to a top of a dielectric body 11. With reference to FIG. 3B, a plurality of bare chips 20 are mounted on the first RDL 10. A plurality of metal bumps 211 on an active surface 21 of each bare chip 20 are correspondingly and electrically connected to inner pads 13 of the first RDL 10. With reference to FIG. 3C, a first encapsulation layer 31 having a CTE closest to a CTE of the dielectric body 11 as compared to other encapsulation layers is selected and formed on the dielectric body 11 and encapsulates the third portion 203 of sidewalls of the bare chips 20 including the metal bumps 211. With reference to FIG. 3D, a third encapsulation layer 33 is formed on the first encapsulation layer 31 and encapsulates the second portion 202 of the sidewalls of the bare chips 20. As shown in FIG. 3E, a second encapsulation layer 32′ is formed on the third encapsulation layer 33 and encapsulates the first portion 201 of the sidewalls of the bare chips 20 including the rear surface 22.

With reference to FIG. 3F, the glass carrier 40 is removed from the first RDL 10 and the outer pads 14 of the first RDL 10 are exposed. With reference to FIG. 3G, the solder balls 14 are correspondingly formed on the outer pads 141 of the first RDL 10 to complete the fan-out package 1b.

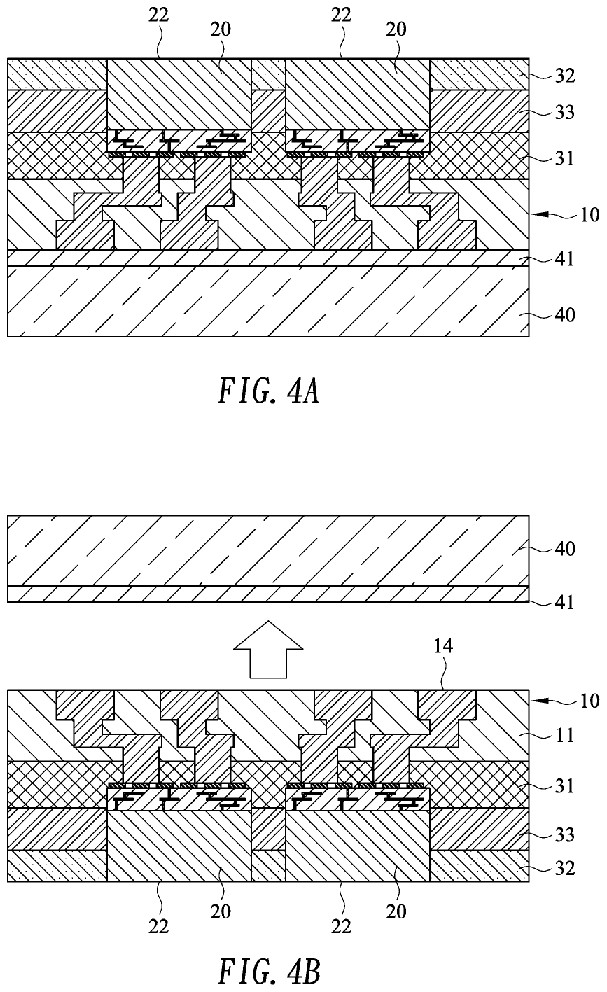

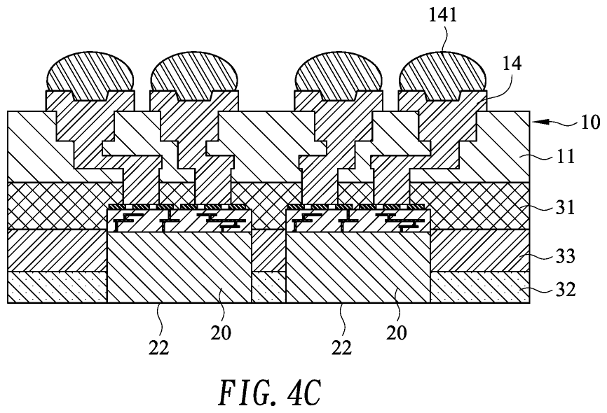

FIGS. 4A to 4C show another RDL-first the fan-out package 1 as shown in FIG. 1F. After the step of forming the second encapsulation layer 32 as shown in FIG. 3E, the second encapsulation layer 32′ is further ground to reduce a thickness of the second encapsulation layer 32 to expose the rear surface 22 of the bare chip 20, as shown in FIG. 4A. The second encapsulation layer 32 and the rear surface 22 of the bare chip 20 are coplanar. With reference to FIG. 4B, the glass carrier 40 is departed from the first RDL 10 and the outer pads 14 are exposed. As shown in FIG. 4C, the solder balls 141 are correspondingly formed on the outer pads 14 to complete the fan-out package 1 as shown in FIG. 1F.

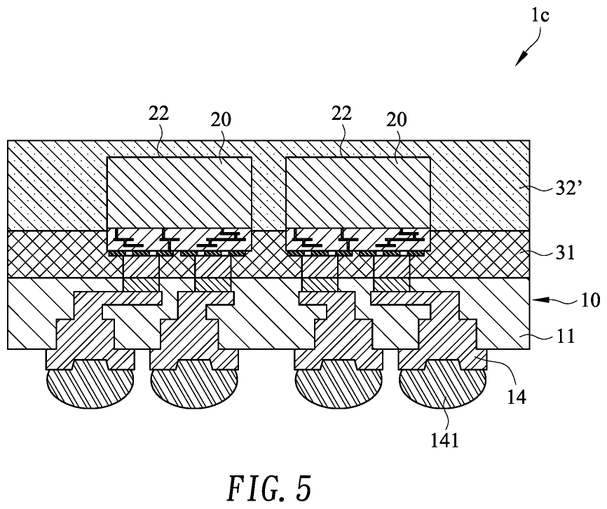

With reference to FIG. 5, a fan-out package 1c according to the fourth embodiment of the present invention is similar to the fan-out package 1b of FIG. 3G, but the fan-out package 1c only has a first encapsulation layer 31 and a second encapsulation layer 32′. A first CTE of the first encapsulation layer 31 is lower than a second CTE of the second encapsulation layer 32′. The first CTE of the first encapsulation layer 31 is closest to a CTE of the dielectric body 11.

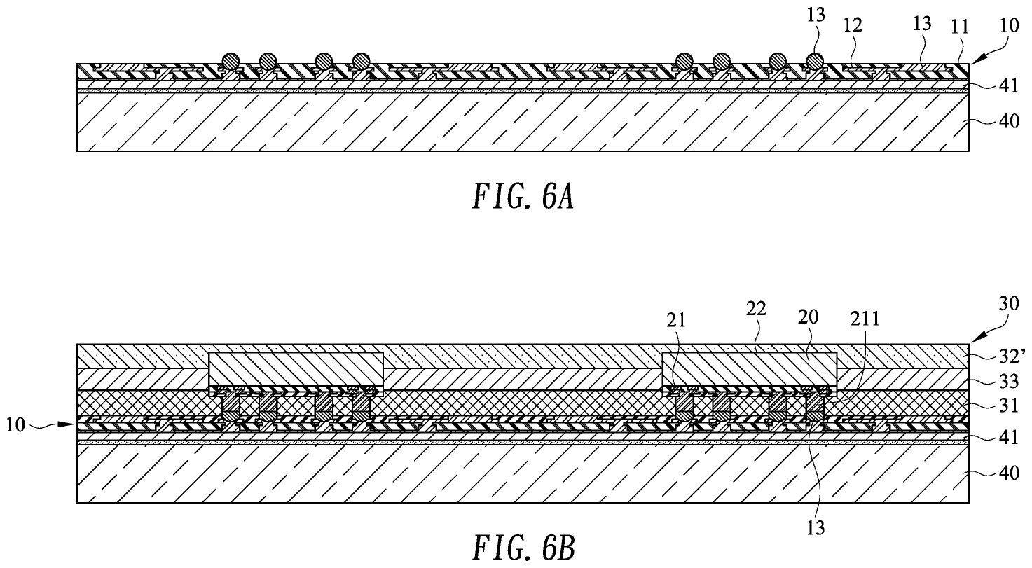

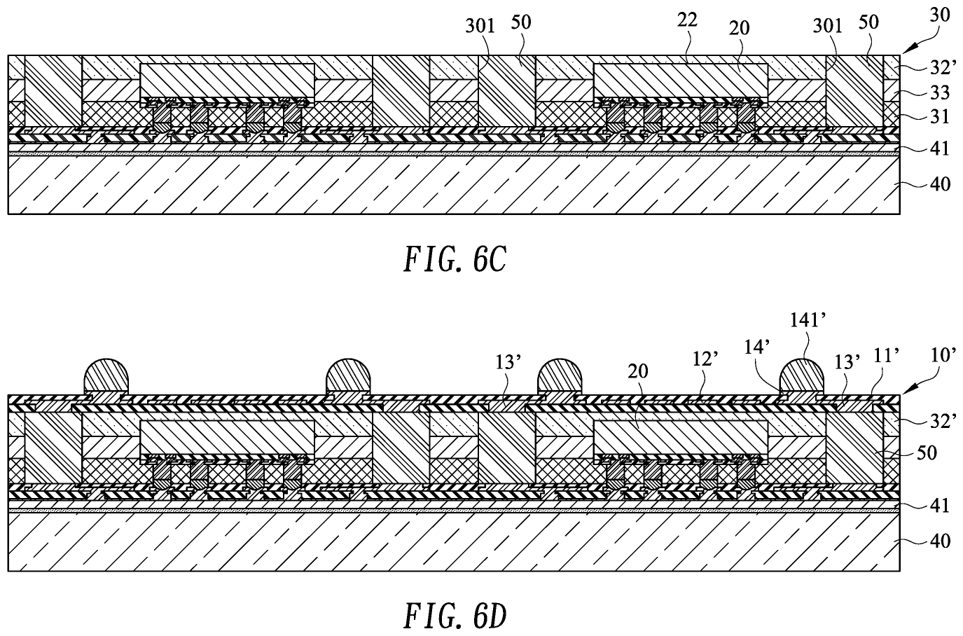

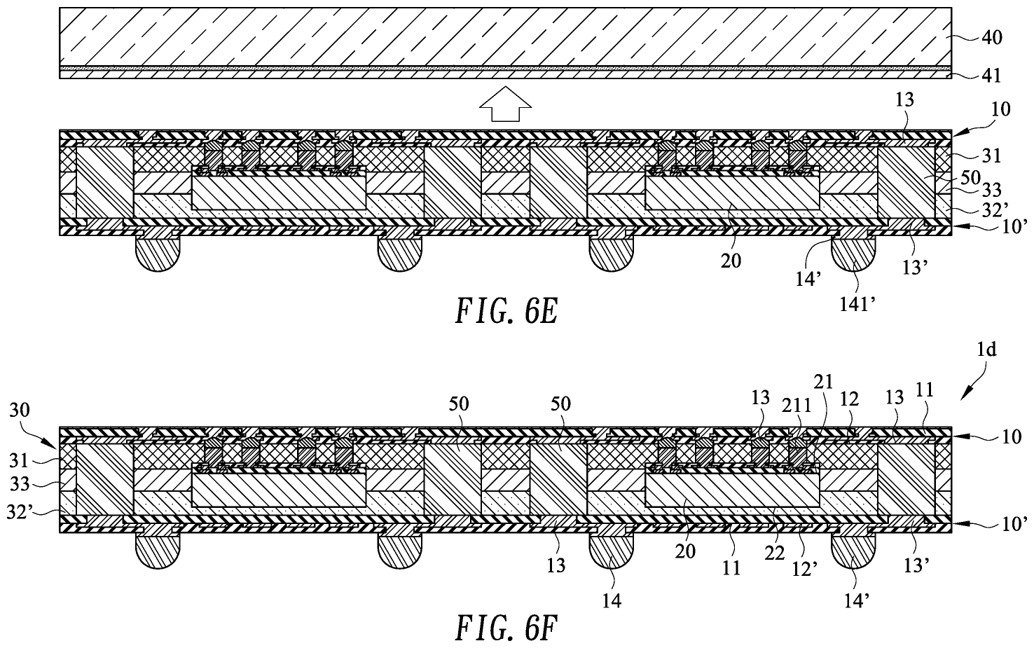

FIG. 6F shows a fan-out package 1d according to a fifth embodiment of the present invention. FIGS. 6A to 6F show a manufacturing method of the fan-out package 1d of FIG. 6F. In the fifth embodiment, the fan-out manufacturing method is a chip-middle manufacturing method. As shown in FIG. 6F, in the fifth embodiment, the fan-out package 1d has a first RDL10, a plurality of bare chips 20, a multi-layer encapsulation 30, a second RDL 10′ and a plurality of metal pillars 50.

The first RDL 10 has a dielectric body 11, a plurality of interconnections 12 and a plurality of inner pads 13. The dielectric body 11 is made of polymer, such as polyimide (PI). The interconnections 12 may electrically connect to the inner pads 13.

Each of the bare chips 20 has an active surface 21 and a rear surface 22 opposite to the active surface 21. The active surface 21 has a plurality of metal bumps 211 electrically connected to the corresponding inner pads 13 of the first RDL 10.

The multi-layer encapsulation 30 is formed between the first RDL 10 and the second RDL 10′ and encapsulates the bare chips 20. The multi-layer encapsulation 30 may have at least two encapsulation layers correspondingly encapsulate different portions of sidewalls of each bare chip 20. In the fifth embodiment, the multi-layer encapsulation 30 has a first encapsulation layer 31, a third encapsulation layer 33 and a second encapsulation layer 32′. The first encapsulation layers 31 has a first CTE, the second encapsulation layer 32′ has a second CTE and the third encapsulation layers 33 has a third CTE. The first and third CTEs are lower than the second CTE.

The second RDL 10′ has a dielectric body 11′, a plurality of interconnections 12′, a plurality of inner pads 13′ and a plurality of outer pads 14′. The dielectric body 11′ is made of polymer, such as polyimide (PI). The interconnections 12′ may are electrically connect the inner pads 13′ to the outer pads 14′. The outer pads 14′ are used to solder another electronic element or a printed circuit board (PCB). The inner pads 13′ are electrically connected to corresponding inner pads 13 of the first RDL 10 through the metal pillars 50, so the first RDL 10 is electrically connected to the second RDL 10′. The metal pillars 50 are formed through the first, third and second encapsulation layers 31, 33 and 32′. Thicknesses of the first to the third encapsulation layer 31 to 33 may be the same or different.

The manufacturing method of the fifth embodiment of the fan-out package 1d shown in FIG. 6F is further described as follow. With reference to FIG. 6A, an adhesive layer 41 is formed on a first surface of a glass carrier 40 and the first RDL 10 is formed on the adhesive layer 41. The inner pads 13 of the first RDL 10 are exposed to a top of the dielectric body 11. With reference to FIG. 6B, the bare chips 20 are respectively mounted on the first RDL 10 and the metal bumps 211 on the active surface 21 of each bare chip 20 are electrically connected to the corresponding inner pads 13 of the first RDL 10. The first, third and second encapsulation layers 31, 33 and 32′ of the first RDL 10 are sequentially formed on the adhesive layer 41 to encapsulate different portions of sidewalls of each bare chip 20. The second encapsulation layer 32′ further covers the rear surface 22 of each bare chip 20. With reference to FIG. 6C, a plurality of through openings 301 are formed through the second, third and first encapsulation layers 32′, 33 and 31. The metal pillars 50 are correspondingly formed in the through openings 301. With reference to FIG. 6D, the second RDL 10′ is formed on the second encapsulation layer 32′ and the metal pillars 50. The outer pads 14′ of the second RDL 10′ are exposed and then the solder balls 141′ are formed on corresponding outer pads.

With reference to FIG. 6E, the glass carrier 40 is departed from the first RDL 10 to complete the fan-out package 1d of FIG. 6F is completed.

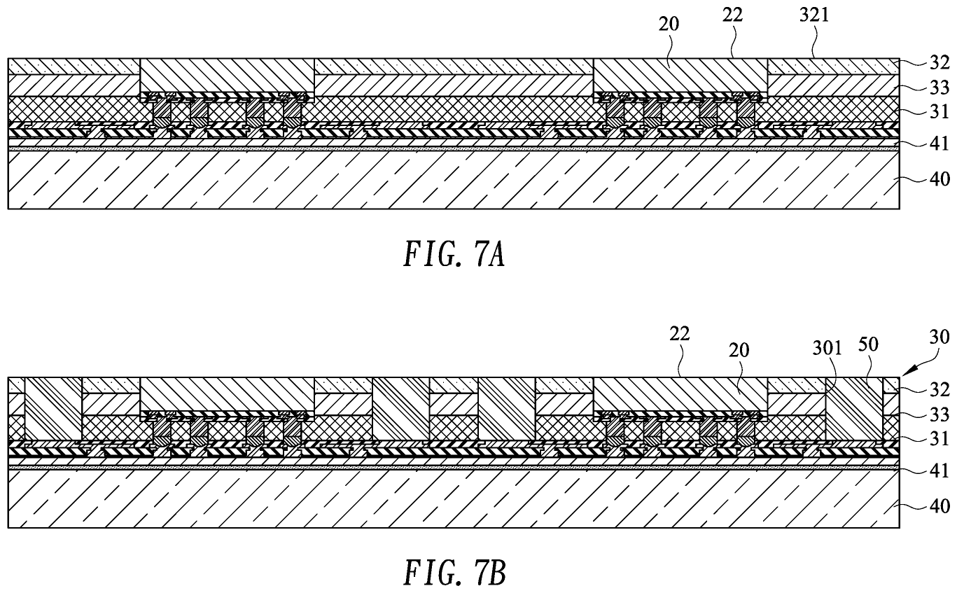

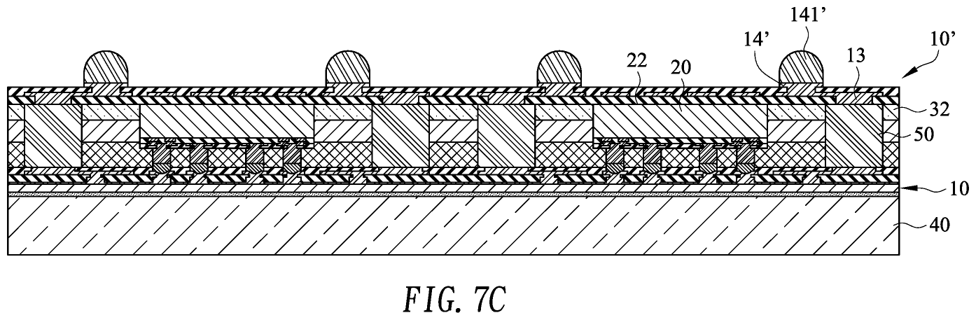

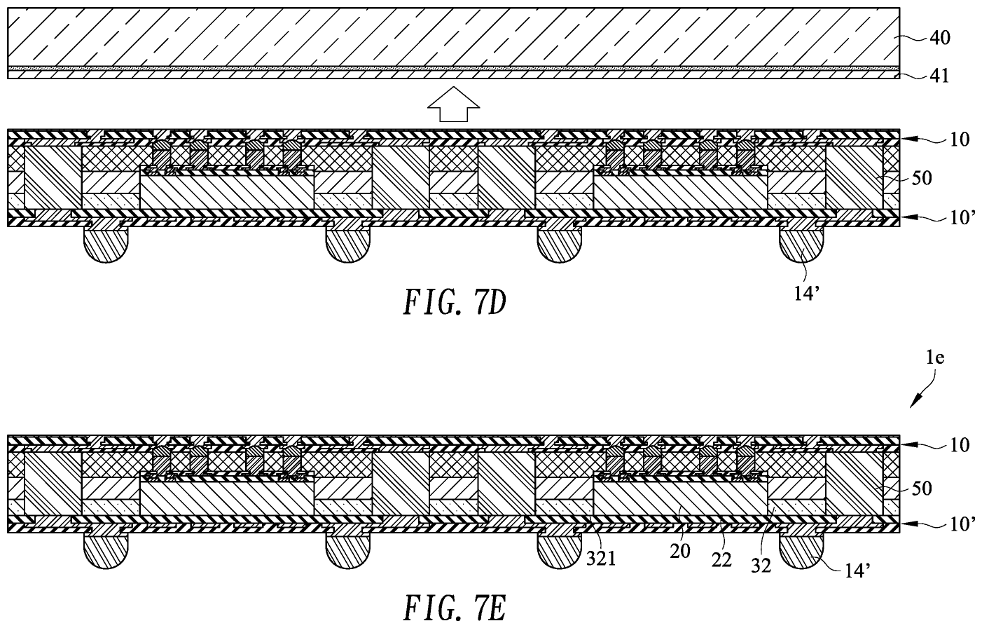

FIG. 7E shows a fan-out package 1e according to a sixth embodiment of the present invention. FIGS. 7A to 7D show a manufacturing method of the fan-out package 1e of FIG. 7E. In the sixth embodiment, the manufacturing method is a middle-chip manufacturing method. After the step of forming second encapsulation layer 32′ as shown in FIG. 6C, a thinning process may be performed on the second encapsulation layer 32′until the rear surface 22 of each bare chip 20 is exposed. The second encapsulation layer 32 and the rear surface 22 of each bare chip 20 are coplanar. With reference to FIG. 7B, a plurality of through openings 301 are formed through the second, third and first encapsulation layers 32, 33 and 31 and a plurality of metal pillars 50 are respectively formed in the through openings 301. With reference to FIG. 7C, a second RDL 10′ is formed on the second encapsulation layer 32, the rear surfaces 22 of the bare chips 20 and the metal pillars 50. With reference to FIG. 7D, the glass carrier 40 is departed from the first RDL 10, and the fan-out package 1e of FIG. 7E is completed.

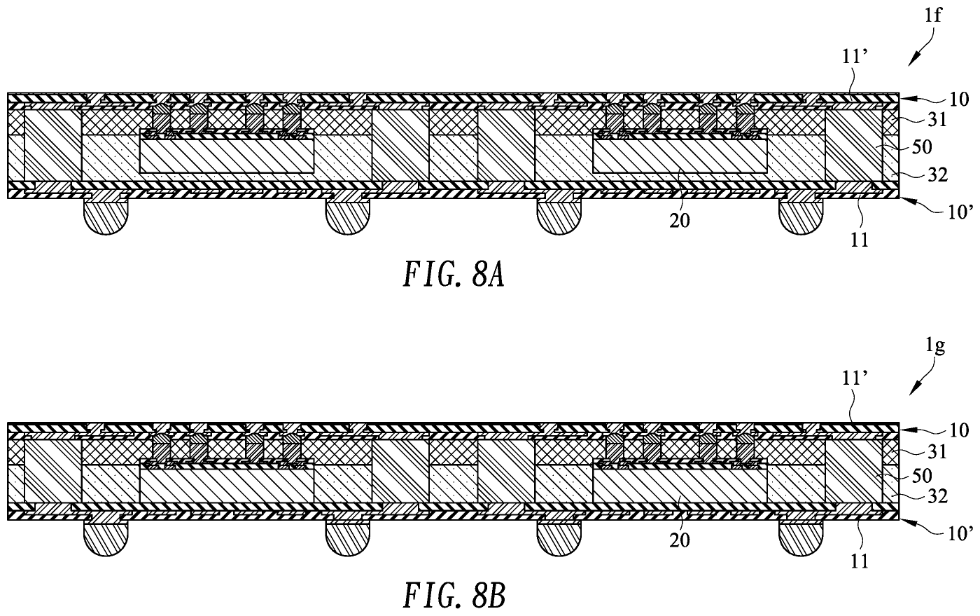

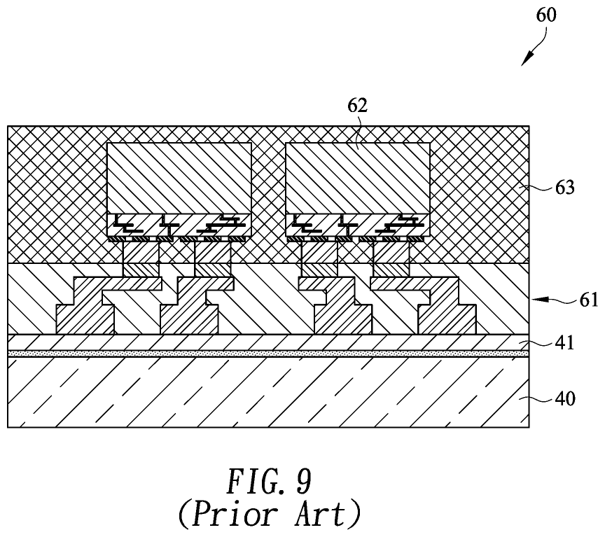

FIG. 8A shows a fan-out package if according to a seventh embodiment of the present invention. The fan-out package if of the seventh embodiment is similar to the fan-out package 1c of FIG. 5, but only has a first encapsulation layer 31 and a second encapsulation layer 32′. A first CTE of the first encapsulation layer 31 and a second CTE of the second encapsulation layer 32′ are closest to a CTE of a dielectric body 11 of a first RDL 10 and a CTE of a dielectric body 11′ of a second RDL 10′.

FIG. 8B shows a fan-out package 1g according to an eighth embodiment of the present invention. The fan-out package 1g of the eighth embodiment is similar to the fan-out package 1e of FIG. 7E, but only has a first encapsulation layer 31 and a second encapsulation layer 32. A first CTE of the first encapsulation layer 31 and a second CTE of the second encapsulation layer 32 are closest to a CTE of a dielectric body 11 of a first RDL 10 and a CTE of a dielectric body 11′ of a second RDL 10′.

Based on the foregoing description, a multi-layer encapsulation is provided in the fan-out package of the present invention. The multi-layer encapsulation has different encapsulation layers with different CTEs and the encapsulation layer with the smallest CTE is close to the RDL. Therefore, in ii the step of forming the multi-layer encapsulation, the suitable CTEs of the encapsulation layers are selected and/or the thicknesses of the encapsulation layers are determined. In the process step with high temperature, the warpage between each encapsulation layer and another material layer close thereto is reduced. In addition, after the step of departing the glass carrier, the warpage of the fan-out package is also reduced by determining suitable CTEs and thickness of each encapsulation layer.

Even though numerous characteristics and advantages of the present invention have been set forth in the foregoing description, together with the details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

1. A fan-out package with warpage reduction, comprising:
a redistribution layer (RDL) having a dielectric body, a plurality of interconnections, a plurality of inner pads and a plurality of outer pads, wherein the interconnections are electrically connected the inner pads to the outer pads;
at least one bare chip having an active surface and a rear surface opposite to the active surface, wherein the active surface has a plurality of metal bumps respectively and electrically connected to the inner pads of the RDL; and
a multi-layer encapsulation mounted on the RDL and encapsulating the at least one bare chip, wherein the multi-layer encapsulation comprises:
a first encapsulation layer encapsulating a first portion of sidewalls of each of the least one bare chip, the metal bumps and the inner pads, wherein the first encapsulation layer has a first coefficient of thermal expansion (CTE); and
a second encapsulation layer formed on the first encapsulation layer to encapsulate a second portion of the sidewalls of each of the least one bare chip, wherein the second encapsulation layer has a second CTE and the first CTE is lower than the second CTE.

2. The fan-out package as claimed in claim 1, wherein a top of the second encapsulation layer and the rear surface of each of the least one bare chip are coplanar.

3. The fan-out package as claimed in claim 1, wherein the second encapsulation layer covers the rear surface of each of the least one bare chip.

4. The fan-out package as claimed in claim 2, further comprising a third encapsulation layer formed between the first encapsulation layer and the second encapsulation layer encapsulating a third portion of the sidewalls of each of the least one bare chip, wherein the third encapsulation layer has a third CTE and the third CTE is lower than the second CTE.

5. The fan-out package as claimed in claim 3, further comprising a third encapsulation layer formed between the first encapsulation layer and the second encapsulation layer encapsulating a third portion of the sidewalls of each of the least one bare chip, wherein the third encapsulation layer has a third CTE and the third CTE is lower than the second CTE.

6. The fan-out package as claimed in claim 1, manufactured by a chip-first manufacturing method using a glass carrier.

7. The fan-out package as claimed in claim 2, manufactured by a chip-first manufacturing method using a glass carrier.

8. The fan-out package as claimed in claim 3, manufactured by a chip-first manufacturing method using a glass carrier.

9. The fan-out package as claimed in claim 1, manufactured by an RDL-first manufacturing method using a glass carrier.

10. The fan-out package as claimed in claim 2, manufactured by an RDL-first manufacturing method using a glass carrier.

11. The fan-out package as claimed in claim 3, manufactured by an RDL-first manufacturing method using a glass carrier.

12. A fan-out package with warpage reduction, comprising:
a first redistribution layer (RDL) having a first dielectric body, a plurality of first interconnections and a plurality of first inner pads, wherein the first interconnections are electrically connected to the first inner pads;
at least one bare chip having an active surface and a rear surface opposite to the active surface, wherein the active surface has a plurality of metal bumps respectively and electrically connected to the first inner pads of the first RDL;
a multi-layer encapsulation mounted on the first RDL and encapsulating the at least one bare chip, wherein the multi-layer encapsulation comprises:
a first encapsulation layer encapsulating a first portion of sidewalls of each of the least one bare chip, the metal bumps and the first inner pads, wherein the first encapsulation layer has a first coefficient of thermal expansion (CTE); and
a second encapsulation layer formed on the first encapsulation layer to encapsulate a second portion of the sidewalls of each of the least one bare chip, wherein the second encapsulation layer has a second CTE and the first CTE is lower than the second CTE; and
a second RDL formed on a top of the second encapsulation layer and having a second dielectric body, a plurality of second interconnections, a plurality of second inner pads and a plurality of second outer pads, wherein the second interconnections are electrically connected the second inner pads to the second outer pads.

13. The fan-out package as claimed in claim 12, wherein the top of the second encapsulation layer and the rear surface of each of the least one bare chip are coplanar.

14. The fan-out package as claimed in claim 12, wherein the second encapsulation layer covers the rear surface of each of the least one bare chip.

15. The fan-out package as claimed in claim 13, further comprising a third encapsulation layer formed between the first encapsulation layer and the second encapsulation layer to encapsulate a third portion of the sidewalls of each of the least one bare chip, wherein the third encapsulation layer has a third CTE and the third CTE is lower than the second CTE.

16. The fan-out package as claimed in claim 14, further comprising a third encapsulation layer formed between the first encapsulation layer and the second encapsulation layer to encapsulate a third portion of the sidewalls of each of the least one bare chip, wherein the third encapsulation layer has a third CTE and the first and third CTEs are lower than the second CTE.

17. The fan-out package as claimed in claim 12, manufactured by a chip-middle manufacturing method using a glass carrier.

18. The fan-out package as claimed in claim 13, manufactured by a chip-middle manufacturing method using a glass carrier.

19. The fan-out package as claimed in claim 14, manufactured by a chip-middle manufacturing method using a glass carrier.

20. The fan-out package as claimed in claim 15, manufactured by a chip-middle manufacturing method using a glass carrier.
